(19) United States
(12) Patent Application Publication
(10) Pub. No.: US 2025/0207697 A1
(43) Pub. Date: Jun. 26, 2025

(54) SUBSTRATE PROCESSING APPARATUS

(71) Applicant: JUSUNG ENGINEERING CO., LTD., Gwangju-si, Gyeonggi-do (KR)

(72) Inventors: Ji Hun LEE, Yongin-si, Gyeonggi-do (KR); Jun Young KIM, Yongin-si, Gyeonggi-do (KR); Sang Yun CHA, Yongin-si, Gyeonggi-do (KR); Chul Joo HWANG, Yongin-si, Gyeonggi-do (KR)

(21) Appl. No.: 18/849,471

(22) PCT Filed: Apr. 3, 2023
(86) PCT No.: PCT/KR2023/004423

§ 371 Date: Sep. 23, 2024

(30) Foreign Application Priority Data
Apr. 8, 2022 (KR) 10-2022-0044154

(51) Int. Cl. F16L 21/035; F16L 21/03; H01L 21/67

(52) U.S. Cl. CPC F16L 21/035; F16L 21/03; H01L 21/67017

(57) ABSTRACT

The present inventive concept relates to a substrate processing apparatus comprising: a chamber; a substrate support part for supporting a substrate inside the chamber; a gas injection unit including a plurality of first injection holes for injecting a first process gas toward the substrate and a gas inlet part communicating with the first injection holes and for introducing the first process gas; a gas supply unit including a gas supply connection part connected to the gas inlet part and supplying the first process gas to the gas injection unit; and a sealing part for maintaining airtightness between the gas inlet unit and the gas supply connection unit.

### TECHNICAL FIELD

The present inventive concept relates to a substrate processing apparatus which performs a processing process such as a deposition process on a substrate.

### BACKGROUND ART

Generally, a thin-film layer, a thin-film circuit pattern, or an optical pattern should be formed on a substrate for manufacturing a semiconductor device, a display device, a solar cell, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Through such a processing process on a substrate, a thin film may be manufactured on the substrate.

FIGS. 1 and 2 are schematic side cross-sectional views of a portion of a substrate processing apparatus according to the related art.

Referring to FIGS. 1 and 2, a substrate processing apparatus 100 according to the related art includes a gas injection unit 110 which injects a gas toward a substrate, a gas block 120 which supplies the gas to the gas injection unit 110, and a sealing unit 130 which seals a region between the gas injection unit 110 and the gas block 120.

The gas injection unit 110 includes an injection hole 111 for injecting the gas toward the substrate. The gas block 120 include an emission hole 121 which emits the gas to be supplied to the injection hole 111. The sealing unit 130 is disposed between an upper surface of the gas injection unit 110 and a lower surface of the gas block 120.

As illustrated in FIG. 1, in a state where the upper surface of the gas injection unit 110 contacts the lower surface of the gas block 120, the sealing unit 130 is disposed to surround each of the injection hole 111 and the emission hole 121, and thus, blocks the leakage of the gas.

However, when deformation, such as that thermal deformation occurs in the gas injection unit 110 or sagging occurs in the gas injection unit 110, occurs in the gas injection unit 110 due to heat occurring in a process of performing a processing process on the substrate, as illustrated in FIG. 2, the upper surface of the gas injection unit 110 and the lower surface of the gas block 120 may move relatively, and thus, may be apart from each other. Due to this, the sealing unit 130 may not surround each of the injection hole 111 and the emission hole 121, and thus, may not block the leakage of a gas.

Therefore, the substrate processing apparatus 100 according to the related art has a problem where the quality of a substrate, on which a processing process has been performed, is reduced because particles occur due to the leakage of a gas. Also, in the substrate processing apparatus 100 according to the related art, because the amount of gas wasted due to the leakage of a gas increases, there is a problem where the process cost increases.

### DISCLOSURE

### Technical Problem

The present inventive concept is devised to solve the above-described problem and is for providing a substrate processing apparatus which may prevent a reduction in a sealing force for blocking the leakage of a gas due to sagging caused by a self-weight and heat occurring in a process of performing a processing process on a substrate.

The present inventive concept is for providing a substrate processing apparatus which may decrease the leakage of a gas to reduce the amount of wasted gas, and thus, may reduce the process cost.

### Technical Solution

To accomplish the above-described objects, the present inventive concept may include the following elements.

A substrate processing apparatus according to the present inventive concept may include: a chamber; a substrate supporting unit for supporting a substrate in the chamber; a gas injection unit including a plurality of first injection holes injecting a first process gas toward the substrate, and a gas inflow unit for communicating with the first injection holes and allowing the first process gas to flow in; a gas supply unit for supplying the first process gas to the gas injection unit, the gas supply unit including a gas supply connection unit connected with the gas inflow unit; and a sealing unit for maintaining sealing between the gas inflow unit and the gas supply connection unit.

In the substrate processing apparatus according to the present inventive concept, the gas inflow unit may include an insertion portion inserted into the gas supply connection unit. The sealing unit may be disposed outside the insertion portion to maintain sealing between the gas inflow unit and the gas supply connection unit.

In the substrate processing apparatus according to the present inventive concept, the gas supply connection unit may include an insertion portion inserted into the gas inflow unit. The sealing unit may be disposed outside the insertion portion to maintain sealing between the gas inflow unit and the gas supply connection unit.

### Advantageous Effect

According to the present inventive concept, the following effects may be realized.

The present inventive concept is implemented to prevent a process gas from being leaked through a region between a gas inflow unit and a gas supply connection unit by using a sealing unit even when relative movement occurs due to deformation between a gas injection unit and the gas supply connection unit. Accordingly, the present inventive concept may reduce particles occurring due to the leakage of a process gas, and thus, may enhance the quality of a substrate on which a processing process has been performed. Also, the present inventive concept may reduce the amount of gas wasted due to the leakage of a process gas, thereby decreasing the process cost.

### DESCRIPTION OF DRAWINGS

FIGS. 1 and 2 are schematic side cross-sectional views of a portion of a substrate processing apparatus according to the related art.

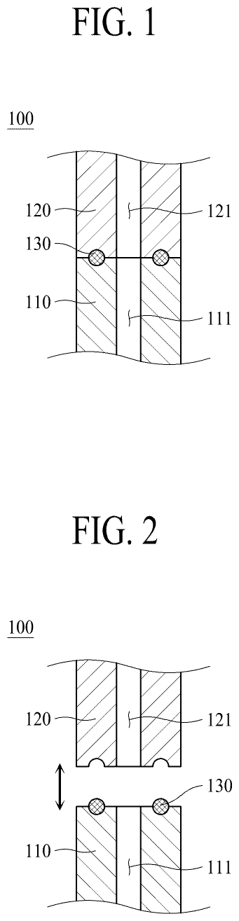

FIG. 3 is a schematic block diagram of a substrate processing apparatus according to the present inventive concept.

FIG. 4 is a schematic perspective view of a substrate supporting unit included in a substrate processing apparatus according to the present inventive concept.

FIGS. 5 and 6 are schematic side cross-sectional views of a gas supply unit, a gas injection unit, and a sealing unit taken along line I-I of FIG. 4.

FIG. 7 is a schematic plan cross-sectional view of a gas inflow unit and a sealing unit taken along line II-II of FIG. 6.

FIG. 8 is a schematic block diagram of a substrate processing apparatus according to the present inventive concept taken along line I-I of FIG. 4.

FIG. 9 is a schematic side cross-sectional view of a gas supply unit, a gas injection unit, a sealing unit, and a lid taken along line I-I of FIG. 4.

FIG. 10 is a schematic plan cross-sectional view of a gas supply connection unit taken along line III-III of FIG. 9.

FIG. 11 is a schematic side cross-sectional view illustrating the enlargement of a region A of FIG. 9.

FIG. 12 is a schematic side cross-sectional view of a gas supply unit, a gas injection unit, a sealing unit, an outer sealing unit, and an inner sealing unit taken along line I-I of FIG. 4.

FIG. 13 is a schematic side cross-sectional view illustrating a shape where a coupling unit couples a gas supply unit to a gas injection unit, with respect to line I-I of FIG. 4.

FIG. 14 is a schematic side cross-sectional view illustrating an embodiment where a gas supply connection unit is inserted into a gas inflow unit, with respect to line I-I of FIG. 4.

### MODE FOR INVENTIVE CONCEPT

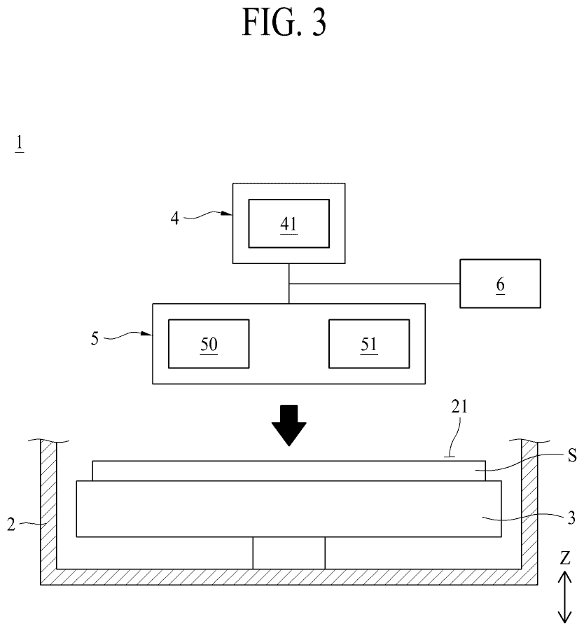

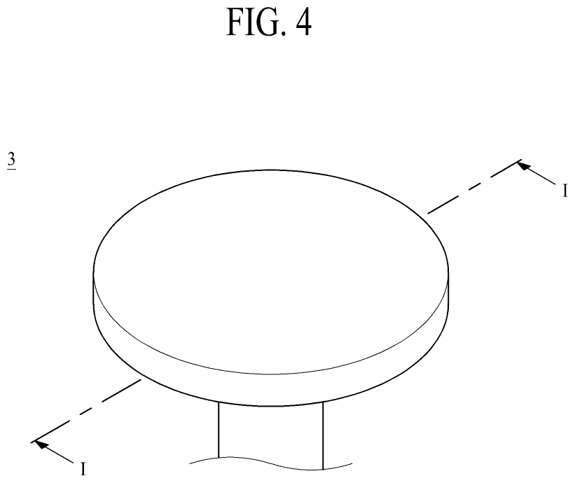

Hereinafter, an embodiment of a substrate processing apparatus according to the present inventive concept will be described in detail with reference to the accompanying drawings. FIG. 3 may be a side cross-sectional view taken along line I-I of FIG. 4.

Referring to FIGS. 3 and 4, a substrate processing apparatus 1 according to the present inventive concept performs a processing process on a substrate S. The substrate S may be a silicon substrate, a glass substrate, a metal substrate, or the like. The substrate processing apparatus 1 according to the present inventive concept may perform a deposition process of depositing a thin film on the substrate S, an etching process of removing a portion of the thin film deposited on the substrate S, etc. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a chamber 2, a substrate supporting unit 3, a gas supply unit 4, a gas injection unit 5, and a sealing unit 6.

### <Chamber>

Referring to FIGS. 3 and 4, the chamber 2 provides a processing space 21. A processing process such as a deposition process and an etching process on the substrate S may be performed in the processing space 21. The processing space 21 may be disposed in the chamber 2. An exhaust port (not shown) which exhausts a gas from the processing space 21 may be coupled to the chamber 2. The substrate supporting unit 3 and the gas injection unit 5 may be disposed in the chamber 2.

### <Substrate Supporting Unit>

Referring to FIGS. 3 and 4, the substrate supporting unit 3 supports the substrate S. The substrate supporting unit 3 may support one substrate S, or may support a plurality of substrates S. In a case where the plurality of substrates S are supported by the substrate supporting unit 3, the processing process may be performed on the plurality of substrates S at a time. The substrate supporting unit 3 may be coupled to the chamber 2. The substrate supporting unit 3 may be disposed in the chamber 2.

### <Gas Supply Unit>

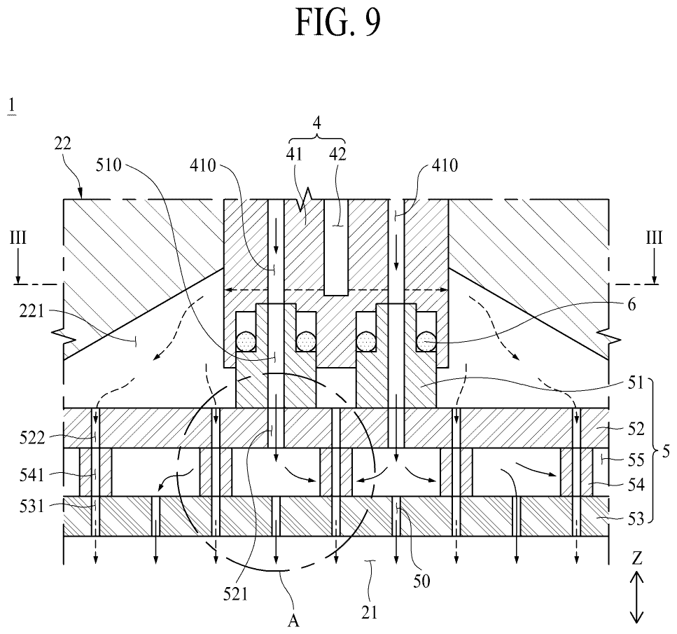

Referring to FIGS. 3 to 5, the gas supply unit 4 is for supplying a first process gas to the gas injection unit 5. The first process gas may be one kind of gas, or may be a mixed gas where several kinds of gases are mixed with one another. The first process gas may be a source gas or a reactant gas. The first process gas may be a mixed gas where a source gas and a reactant gas are mixed with each other. The gas supply unit 4 may be disposed over the gas injection unit 5. The gas supply unit 4 may be inserted into and coupled to a lid 22 (illustrated in FIG. 9) covering an upper portion of the chamber 2.

The gas supply unit 4 may include a gas supply connection unit 41.

The gas supply connection unit 41 is supplied with the first process gas from the outside. The gas supply connection unit 41 may be connected with a gas storage unit (not shown) disposed in the outside. The gas storage unit is for storing the first process gas. The gas supply connection unit 41 may be supplied with the first process gas from the gas storage unit. The gas supply connection unit 41 may be connected with the gas storage unit through a pipe, hose, or the like. The gas supply connection unit 41 may be directly connected with the gas storage unit.

The gas supply connection unit 41 may include a first gas supply hole 410. The first gas supply hole 410 is supplied with the first process gas. The first gas supply hole 410 may be supplied with the first process gas from the outside. The first gas supply hole 410 may be connected with the gas storage unit through a pipe, hose, or the like. The first gas supply hole 410 may be directly connected with the gas storage unit. The first gas supply hole 410 may be formed to pass through the gas supply connection unit 41.

The gas supply connection unit 41 may be connected with the gas injection unit 5. One side of the gas supply connection unit 41 may be connected with the gas injection unit 5, and the other side of the gas supply connection unit 41 may be connected with the gas storage unit. The gas supply connection unit 41 may supply the first process gas, supplied from the gas storage unit, toward the gas injection unit 5. Accordingly, the first process gas may be supplied from the gas supply unit 4 to the gas injection unit 5 and may be injected to the substrate S through the gas injection unit 5.

The gas supply connection unit 41 may include the first gas supply hole 410. The first gas supply hole 410 is for supplying the first process gas. The first process gas may be supplied from the gas storage unit to the first gas supply hole 410 and may flow along the first gas supply hole 410, and then, may be emitted from the first gas supply hole 410 and may be supplied to the gas injection unit 5. The first gas supply hole 410 may be formed to pass through the gas supply connection unit 41.

### <Gas Injection Unit>

Referring to FIGS. 3 to 5, the gas injection unit 5 injects a gas toward the substrate S. The gas injection unit 5 may be disposed in the chamber 2. The gas injection unit 5 may be disposed to be opposite to the substrate supporting unit 3. The gas injection unit 5 may be disposed over the substrate supporting unit 3. In this case, the gas injection unit 5 and the substrate supporting unit 3 may be disposed apart from each other in a vertical direction (a Z-axis direction). The processing space 21 may be disposed between the gas injection unit 5 and the substrate supporting unit 3. The gas injection unit 5 may be coupled to the chamber 2. The gas injection unit 5 may be coupled to the lid 22 (illustrated in FIG. 9).

The gas injection unit 5 may be connected with the gas supply unit 4. In this case, an upper surface of the gas injection unit 5 may be connected with the gas supply unit 4, and a lower surface of the gas injection unit 5 may be disposed to face the substrate supporting unit 3. Therefore, the gas injection unit 5 may inject the first process gas, supplied from the gas supply unit 4, toward the substrate supporting unit 3.

The gas injection unit 5 may include a plurality of first injection holes 50 and a gas inflow unit 51.

The first injection holes 50 are for injecting the first process gas. The first process gas may be injected toward the substrate S through the first injection holes 50. The first injection holes 50 may be connected with the gas inflow unit 51 and may be connected with the gas supply unit 4 through the gas inflow unit 51. The first injection holes 50 may be formed to pass through the lower surface of the gas injection unit 5. The first injection holes 50 may be disposed at positions apart from one another.

The gas inflow unit 51 is for allowing the first process gas to flow in. The gas inflow unit 51 may be connected with the gas supply unit 4. Therefore, the first process gas emitted from the gas supply unit 4 may flow into the gas inflow unit 51. The first process gas may flow from the gas supply unit 4 into the gas inflow unit 51, and then, may be injected toward the substrate S through the first injection holes 50.

The gas inflow unit 51 may be inserted into the gas supply connection unit 41. Accordingly, the first process gas emitted from the gas supply connection unit 41 may flow into the gas inflow unit 51. The gas inflow unit 51 may be inserted into the gas supply connection unit 41, and thus, may be movably coupled to the gas supply connection unit 41 in the vertical direction (the Z-axis direction).

The gas inflow unit 51 may include a gas inflow hole 510. The gas inflow hole 510 is for allowing the first process gas to flow in. One side of the gas inflow hole 510 may be disposed to face the first gas supply hole 410. Therefore, the first process gas may be emitted from the first gas supply hole 410, and then, may flow into the gas inflow unit 51 through the gas inflow hole 510. The other side of the gas inflow hole 510 may be disposed to face the first injection holes 50. Accordingly, the first process gas may be emitted from the gas inflow hole 510 and then may be supplied to the first injection holes 50, and may be injected to the substrate S through the first injection holes 50. The gas inflow hole 510 may be formed to pass through the gas inflow unit 51.

The gas inflow unit 51 may include an insertion portion 511. The insertion portion 511 is inserted into the gas supply connection unit 41. The insertion portion 511 may be formed to protrude toward the gas supply connection unit 41. The gas inflow hole 510 may be formed to pass through the insertion portion 511. The insertion portion 511 may correspond to an upper portion of the gas inflow unit 51.

### <Sealing Unit>

Referring to FIGS. 3 to 6, the sealing unit 6 is for prevent the leakage of the first process gas between the gas inflow unit 51 and the gas supply connection unit 41. The sealing unit 6 may be coupled to at least one of the gas inflow unit 51 and the gas supply connection unit 41. When the insertion portion 511 is inserted into the gas supply connection unit 41, the sealing unit 6 may be disposed outside the insertion portion 511. Therefore, the sealing unit 6 may be disposed to maintain sealing between the gas inflow unit 51 and the gas supply connection unit 41, in the gas supply connection unit 41. Accordingly, the substrate processing apparatus 1 according to the present inventive concept may realize the following effects.

First, due to heat occurring in a process of performing a processing process on the substrate S, thermal deformation may occur in at least one of the gas injection unit 5 and the gas supply unit 4 or sagging may occur in at least one of the gas injection unit 5 and the gas supply unit 4, and due to several causes, the gas injection unit 5 and the gas supply unit 4 may move relatively in the vertical direction (the Z-axis direction). For example, when sagging occurs in the gas injection unit 5, as illustrated by a dotted-line arrow in FIG. 6, the gas injection unit 5 may relatively move to be apart from the gas supply unit 4. For example, when the gas supply unit 4 is contracted by cooling, as illustrated by the dotted-line arrow in FIG. 6, the gas supply unit 4 may relatively move to be apart from the gas injection unit 5. As described above, as relative movement occurs between the gas injection unit 5 and the gas supply unit 4, relative movement occurs between the gas inflow unit 51 and the gas supply connection unit 41.

Subsequently, as described above, even when relative movement occurs between the gas inflow unit 51 and the gas supply connection unit 41, because the sealing unit 6 is disposed outside the insertion portion 511, the substrate processing apparatus 1 according to the present inventive concept may maintain sealing while allowing relative movement between the gas inflow unit 51 and the gas supply connection unit 41. Therefore, even when relative movement caused by deformation occurs between the gas injection unit 5 and the gas supply connection unit 41, the substrate processing apparatus 1 according to the present inventive concept may prevent the first process gas from being leaked through a gap between the gas inflow unit 51 and the gas supply connection unit 41 by using the sealing unit 6. Accordingly, the substrate processing apparatus 1 according to the present inventive concept may reduce particles which occur due to the leakage of the first process gas, and thus, may enhance the quality of the substrate S on which the processing process has been performed. Also, the substrate processing apparatus 1 according to the present inventive concept may decrease the amount of gas wasted due to the leakage of the first process gas, thereby reducing the process cost.

The sealing unit 6 may allow the relative movement of the gas inflow unit 51 with respect to the gas supply connection unit 41 or may allow the relative movement of the gas supply connection unit 41 with respect to the gas inflow unit 51, while maintaining sealing between the gas inflow unit 51 and the gas supply connection unit 41. Accordingly, the substrate processing apparatus 1 according to the present inventive concept may maintain sealing between the gas supply connection unit 41 and the gas inflow unit 51 by using the sealing unit 6, regardless of that one of the gas supply connection unit 41 and the gas inflow unit 51 moves.

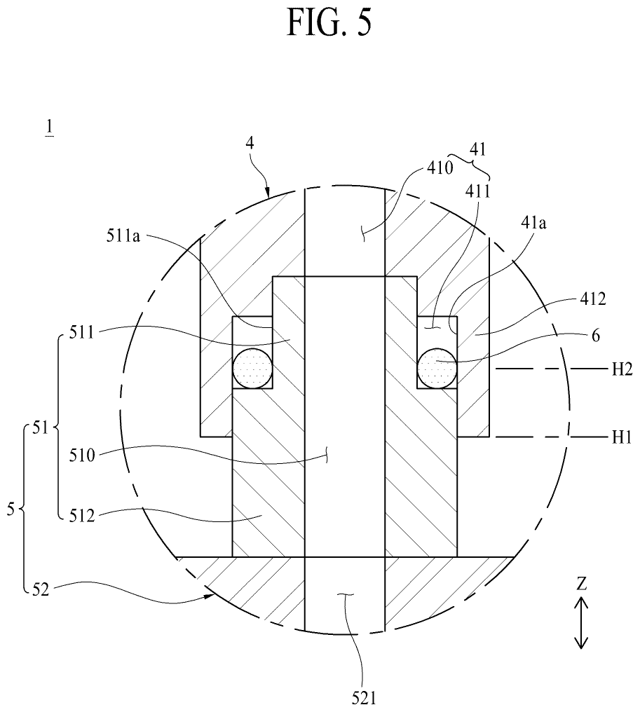

A movement range, which enables the sealing unit 6 to maintain sealing while allowing relative movement between the gas inflow unit 51 and the gas supply connection unit 41, may be determined based on a length which is maintained in a state where the gas inflow unit 51 is inserted into the gas supply connection unit 41. For example, as illustrated in FIG. 5, the sealing unit 6 may maintain sealing while allowing relative movement between the gas inflow unit 51 and the gas supply connection unit 41, within a movement range where a height H1 of a lower surface of the gas supply connection unit 41 reaches a height H2 of the sealing unit 6. The gas supply connection unit 41 and the gas inflow unit 51 may be maintained with contacting the sealing unit 6 within the movement range.

The sealing unit 6 may be inserted into the gas supply connection unit 41. Therefore, the sealing unit 6 may contact each of the gas supply connection unit 41 and the gas inflow unit 51 in the gas supply connection unit 41, and thus, may maintain sealing between the gas inflow unit 51 and the gas supply connection unit 41 which move relatively. In this case, the gas supply connection unit 41 may include an insertion groove 411. The insertion groove 411 may be implemented as a groove which is formed by a certain depth from the lower surface of the gas supply connection unit 41. The insertion groove 411 may be formed to be connected with the first gas supply hole 410.

The insertion portion 511 may be inserted into the insertion groove 411. The insertion portion 511 may be inserted into the insertion groove 411 so as to be movable in the vertical direction (the Z-axis direction). In a case where the insertion portion 511 is provided, the sealing unit 6 may contact each of an inner surface 41a of the gas supply connection unit 41 and an outer surface 511a of the insertion portion 511 so as to maintain sealing between the gas inflow unit 51 and the gas supply connection unit 41. The inner surface 41a of the gas supply connection unit 41 is an inner surface which is disposed to face the insertion groove 411. The outer surface 511a of the insertion portion 511 is an outer surface which is disposed to face the inner surface 41a of the gas supply connection unit 41 with being inserted into the insertion groove 411. The sealing unit 6 may maintain sealing while allowing relative movement of the gas inflow unit 51 and the gas supply connection unit 41 within a range maintaining a state where the sealing unit 6 contacts each of the inner surface 41a of the gas supply connection unit 41 and the outer surface 511a of the insertion portion 511. The sealing unit 6 may be coupled to the insertion portion 511 to surround the outer surface 511a of the insertion portion 511.

An inflow body 512 including the gas inflow unit 51 may be inserted into the insertion groove 411. The inflow body 512 may be inserted into the insertion groove 411 so as to be movable in the vertical direction (the Z-axis direction). The insertion portion 511 may protrude from an upper surface of the inflow body 512. A horizontal cross-sectional area of the inflow body 512 may be implemented to be greater than that of the insertion portion 511. A horizontal cross-sectional area is set with respect to a horizontal direction perpendicular to the vertical direction (the Z-axis direction). The sealing unit 6 may be coupled to the insertion portion 511 and may be disposed over the inflow body 512. In this case, the upper surface of the inflow body 512 may support the sealing unit 6, and thus, may limit a distance by which the sealing unit 6 is movable downward. Therefore, the sealing unit 6 may be solidly maintained with contacting each of the inner surface 41a of the gas supply connection unit 41 and the outer surface 511a of the insertion portion 511. The gas inflow hole 510 may be formed to pass through all of the inflow body 512 and the insertion portion 511.

The gas supply connection unit 41 may include a cover portion 412, so as to increase a distance maintained in a state where the sealing unit 6 contacts the inner surface 41a of the gas supply connection unit 41. The cover portion 412 may protrude downward to cover a portion of an outer surface of the inflow body 512. An inner surface of the cover portion 412 may be included in the inner surface 41a of the gas supply connection unit 41. Therefore, a length of the inner surface 41a of the gas supply connection unit 41 increases by a length by which the cover portion 412 protrudes downward. Accordingly, the substrate processing apparatus 1 according to the present inventive concept may increase a length which enables the sealing unit 6 to maintain sealing while allowing relative movement between the gas inflow unit 51 and the gas supply connection unit 41 by using the cover portion 412.

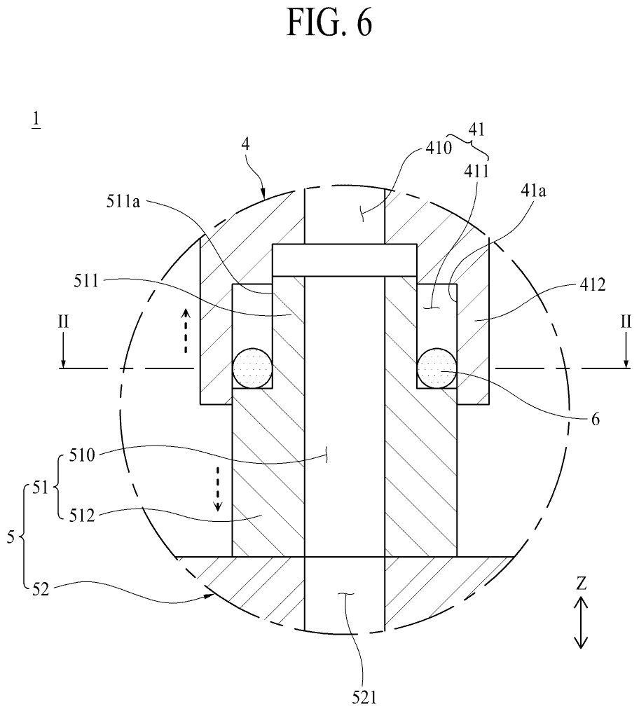

Referring to FIGS. 3 to 7, the sealing unit 6 may form an oval shape along the outer surface 511a of the insertion portion 511 and may be coupled to the insertion portion 511. In this case, the outer surface 511a of the insertion portion 511 may be formed to include a horizontal cross-sectional surface having an oval shape. The horizontal cross-sectional surface is set with respect to the horizontal direction. In a case where the outer surface 511a of the insertion portion 511 is formed to include the horizontal cross-sectional surface having an oval shape, the inner surface 41a of the gas supply connection unit 41 may be formed to include a horizontal cross-sectional surface having an oval shape. Accordingly, the substrate processing apparatus 1 according to the present inventive concept may increase a contact area where the sealing unit 6 contacts each of the outer surface 511a of the insertion portion 511 and the inner surface 41a of the gas supply connection unit 41, and thus, may more reinforce a sealing force using the sealing unit 6.

The sealing unit 6 may seal the gap between the gas supply connection unit 41 and the gas inflow unit 51 so as to prevent the leakage of the first process gas which flows from the first gas supply hole 410 to the gas inflow hole 510. The first gas supply hole 410 may be formed to include a horizontal cross-sectional surface having an oval shape. The gas inflow hole 510 may be formed to include a horizontal cross-sectional surface having an oval shape. Therefore, comparing with a comparative example where each of the first gas supply hole 410 and the gas inflow hole 510 is formed to include a horizontal cross-sectional surface having an oval shape, the substrate processing apparatus 1 according to the present inventive concept is implemented to increase the amount of flow of the first process gas by using the first gas supply hole 410 and the gas inflow hole 510 which are formed to include the horizontal cross-sectional surface having an oval shape. Accordingly, the substrate processing apparatus 1 according to the present inventive concept may more enhance the efficiency of a processing process using the first process gas. In this case, each of the outer surface 511a of the insertion portion 511 and the inner surface 41a of the gas supply connection unit 41 may be formed to include a horizontal cross-sectional surface having an oval shape. The sealing unit 6 may form an oval shape along the outer surface 511a of the insertion portion 511 and may seal the gap between the gas inflow unit 51 and the gas supply connection unit 41.

Furthermore, the substrate processing apparatus 1 according to the present inventive concept may be implemented to spatially separate and move the first process gas and a second process gas and then inject the first process gas and the second process gas toward the substrate S. To this end, the gas injection unit 5 and the gas supply unit 4 may be implemented as follows.

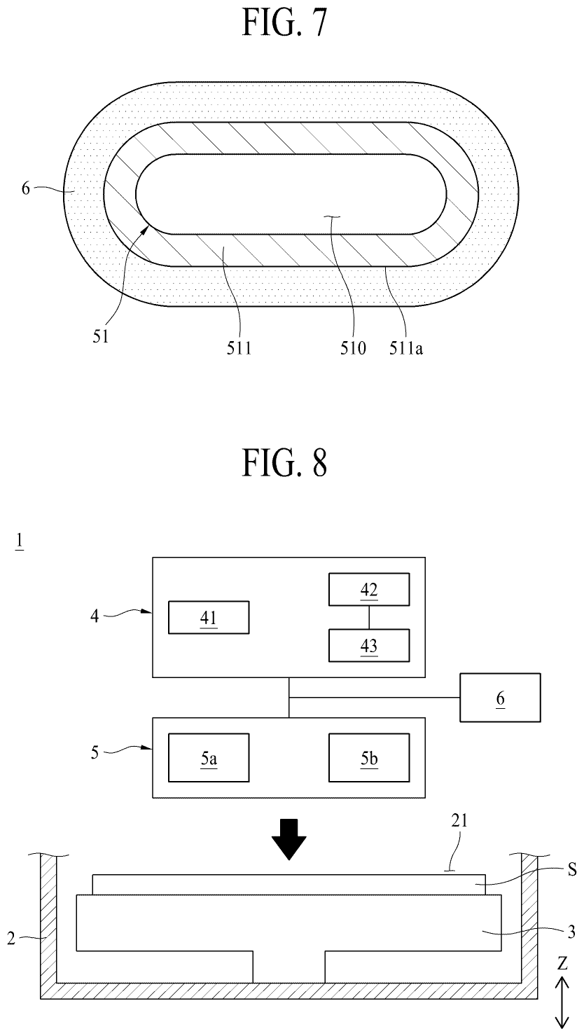

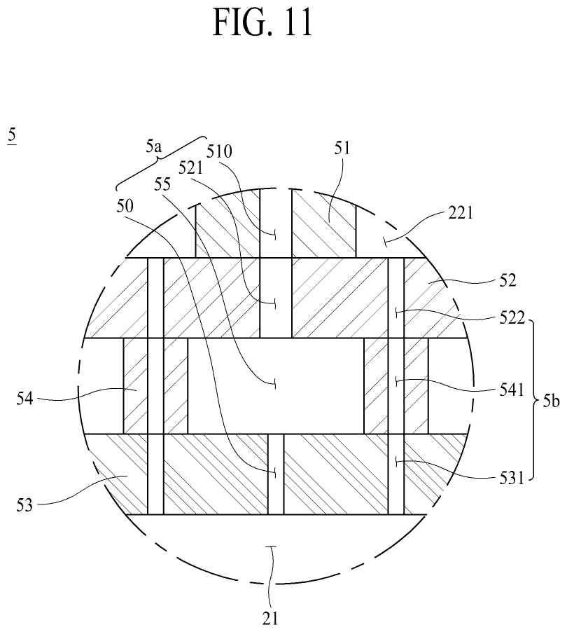

Referring to FIGS. 3 to 11, the gas injection unit 5 may include a first gas flow path 5a and a second gas flow path 5b.

The first gas flow path 5a is a path through which the first process gas flows. The first process gas may be injected to the substrate S through the first gas flow path 5a. The first gas flow path 5a may function as a flow path for allowing the first process gas to flow and may function as an injection port for injecting the first process gas into the processing space 21. The first gas flow path 5a may be connected with the gas inflow unit 51 and may be connected with the gas supply connection unit 41 through the gas inflow unit 51. Accordingly, the first process gas may be supplied to the first gas flow path 5a via the gas supply connection unit 41 and the gas inflow unit 51 and may be injected into the processing space 21 through the first gas flow path 5a. In this case, the first process gas may be supplied to the first gas flow path 5a through the first gas supply hole 410 and the gas inflow hole 510.

The second gas flow path 5b is a path through which the second process gas flows. The second process gas and the first process gas may be different gases. For example, the one of the first process gas and the second process gas may be a source gas, and the other of the first process gas and the second process gas may be a reactant gas. The second process gas may be injected to the substrate S through the second gas flow path 5b. The second gas flow path 5b may function as a flow path for allowing the second process gas to flow and may function as an injection port for injecting the second process gas into the processing space 21. The second process gas passing through a second gas supply hole 42 and a gas emission hole 43 included in the gas supply unit 4 may flow into the second gas flow path 5b. The second gas supply hole 42 is supplied with the second process gas. The second gas supply hole 42 may be supplied with the second process gas from the gas storage unit. The gas emission hole 43 is a hole through which the second process gas is emitted. The gas emission hole 43 may be formed to be connected with the second gas supply hole 42. Accordingly, the second process gas may be supplied to the second gas flow path 5b via the second gas supply hole 42 and the gas emission hole 43 and may be injected into the processing space 21 through the second gas flow path 5b.

The second gas flow path 5b and the first gas flow path 5a may be disposed to be spatially separated from each other. Therefore, the first process gas may be injected into the processing space 21 through the first gas flow path 5a without passing through the second gas flow path 5b. The second process gas may be injected into the processing space 21 through the second gas flow path 5b without passing through the first gas flow path 5a. In this case, the first gas supply hole 410 and the gas inflow hole 510 may be formed to be spatially separated from the second gas supply hole 42 with respect to the gas emission hole 43. Accordingly, the first process gas and the second process gas may flow without being mixed with each other in the gas supply unit 4 and may be supplied to each of the first gas flow path 5a and the second gas flow path 5b.

The gas injection unit 5 may include an upper plate 52 and a lower plate 53.

The upper plate 52 is disposed over the lower plate 53. The upper plate 52 and the lower plate 53 may be disposed apart from each other in the vertical direction (the Z-axis direction). With respect to the vertical direction (the Z-axis direction), the upper plate 52 may be disposed between the gas inflow unit 51 and the lower plate 53. The gas inflow unit 51 may protrude upward from an upper surface of the upper plate 52. The gas inflow unit 51 and the upper plate 52 may be provided as one body.

The upper plate 52 may include a first connection hole 521 and a second connection hole 522.

The first connection hole 521 is for providing the first process gas. The first connection hole 521 may be formed to pass through the upper plate 52. The first connection hole 521 may be connected with the gas inflow hole 510. Accordingly, the first process gas emitted from the first gas supply hole 410 may flow into the first connection hole 521 via the gas inflow hole 510. The first connection hole 521 may be included in the first gas flow path 5a.

The upper plate 52 may include the first connection hole 521 provided in plurality. The first connection holes 521 may be formed to pass through the upper plate 52, at positions apart from one another. In a case where the first connection hole 521 is provided in plurality, the gas injection unit 5 may include the gas inflow unit 51 provided in plurality. In this case, the gas supply unit 4 may include the first gas supply hole 410 provided in plurality. The gas inflow unit 51, the first gas supply hole 410, and the first connection hole 521 may be provided as a same number.

The second connection hole 522 is for providing the second process gas. The second connection hole 522 may be formed to pass through the upper plate 52. The second process gas emitted from the gas emission hole 43 may flow into the second connection hole 522. In this case, the second process gas may be emitted from the gas emission hole 43 and may be supplied to a diffusion portion 221 (illustrated in FIG. 9) formed in the lid 22, and then, may be supplied from the diffusion portion 221 to the second connection hole 522. The diffusion portion 221 may be implemented as a groove which is formed by a certain depth in a lower surface of the lid 22. The second connection hole 522 may be included in the second gas flow path 5b. The second connection hole 522 and the first connection hole 521 may be formed to pass through the upper plate 52 at positions apart from each other.

The upper plate 52 may include the second connection hole 522 provided in plurality. The second connection holes 522 may be formed to pass through the upper plate 52 at positions apart from one another. The second process gas emitted from the gas emission hole 43 may flow into each of the second connection holes 522 via the diffusion portion 221. In this case, the diffusion portion 221 may be formed in a shape where a size of a horizontal cross-sectional surface increases progressively as the diffusion portion 221 extends downward. For example, the diffusion portion 221 may be formed in a circular truncated cone shape.

The lower plate 53 is disposed over the substrate supporting unit 3. With respect to the vertical direction (the Z-axis direction), the lower plate 53 may be disposed between the substrate supporting unit 3 and the upper plate 52. The lower plate 53 may be disposed so that an upper surface thereof faces a lower surface of the upper plate 52.

The lower plate 53 may include the first injection holes 50 and a plurality of second injection holes 531.

The first injection holes 50 are for injecting the first process gas. The first injection holes 50 may be formed to pass through the lower plate 53. The first injection holes 50 may be formed to pass through the lower plate 53 at positions apart from one another.

The second injection holes 531 are for injecting the second process gas. The second injection holes 531 may be formed to pass through the lower plate 53. The second injection holes 531 may be formed to pass through the lower plate 53 at positions apart from one another. The second injection holes 531 and the first injection holes 50 may be disposed apart from one another.

The gas injection unit 5 may include a plurality of flow path protrusions 54 and a buffer portion 55.

The flow path protrusions 54 are disposed between the lower plate 53 and the upper plate 52. The flow path protrusions 54 may be disposed apart from each other. A flow path hole 541 may be formed in each of the flow path protrusions 54. The flow path holes 541 may be formed to respectively pass through the flow path protrusions 54. The flow path holes 541 may be respectively connected at the second connection holes 522 at one side thereof, and the other sides may be respectively connected with the second injection holes 531. Therefore, the second process gas may flow along the second connection holes 522, the flow path holes 541, and the second injection holes 531 and may be injected toward the substrate S. The second connection holes 522, the flow path holes 541, and the second injection holes 531 may be provided in the second gas flow path 5b. In this case, the diffusion portion 221 may transfer the second process gas, emitted from the gas emission hole 43, to the second gas flow path 5b. The diffusion portion 221 may transfer the second process gas to each of the second connection holes 522 included in the second gas flow path while diffusing the second process gas.

The buffer portion 55 is disposed outside the flow path protrusions 54, between the lower plate 53 and the upper plate 52. The buffer portion 55 may function as a diffusion space where the first process gas is diffused. The buffer portion 55 may be connected with the first connection hole 521 at one side thereof, and the other side may be connected with the first injection holes 50. Therefore, the first process gas may flow along the first connection hole 521, the buffer portion 55, and the first injection holes 50 and may be injected toward the substrate S. The first connection hole 521, the buffer portion 55, and the first injection holes 50 may be included in the first gas flow path 5a. In a case where the first connection hole 521 is provided in plurality, the first connection holes 521 may be connected with the buffer portion 55 at positions apart from one another.

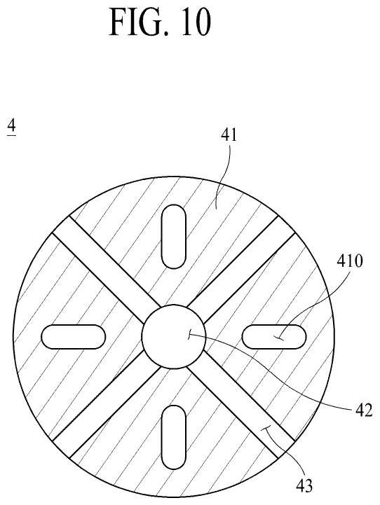

Here, the gas supply unit 4 may include the gas emission hole 43 provided in plurality. Each of the gas emission holes 43 may be connected with the second gas supply hole 42 at one side thereof, and the other sides may be connected with the diffusion portion 221 at different positions. In this case, the gas emission holes 43 may extend in different directions with respect to the second gas supply hole 42 and may be formed to pass through a side surface of the gas supply unit 4. For example, as illustrated in FIG. 10, four gas emission holes 43 may be formed to extend in different directions with respect to the second gas supply hole 42. Through the gas emission holes 43, the substrate processing apparatus 1 according to the present inventive concept may increase a diffusion force with which the second process gas is diffused in the diffusion portion 221. Therefore, the substrate processing apparatus 1 according to the present inventive concept may decrease a deviation of a flow rate of the second process gas supplied to the second connection holes 522. Accordingly, the substrate processing apparatus 1 according to the present inventive concept may be implemented to uniformly inject the second process gas to the substrate S, and thus, may enhance the quality of the substrate S on which a processing process using the second process gas has been performed.

Furthermore, the gas supply connection unit 41 may include the first gas supply hole 410 provided in plurality. In this case, as illustrated in FIG. 10, each of the first gas supply holes 410 may be disposed between the gas emission holes 43 in a circumference direction with respect to the second gas supply hole 42. Accordingly, the substrate processing apparatus 1 according to the present inventive concept may increase the amount of supply of each of the first process gas and the second process gas through first gas supply holes 410 and the gas emission holes 43 and may compactly implement a size of the gas supply unit 4. Also, the substrate processing apparatus 1 according to the present inventive concept may reduce a position deviation between the first process gas flowing along the first gas supply holes 410 and the second process gas flowing along the gas emission holes 43, and thus, may decrease a quality difference between a processing process using the first process gas and a processing process using the second process gas. Therefore, the substrate processing apparatus 1 according to the present inventive concept may more enhance the quality of the substrate S on which a processing process using the first process gas and the second process gas has been performed.

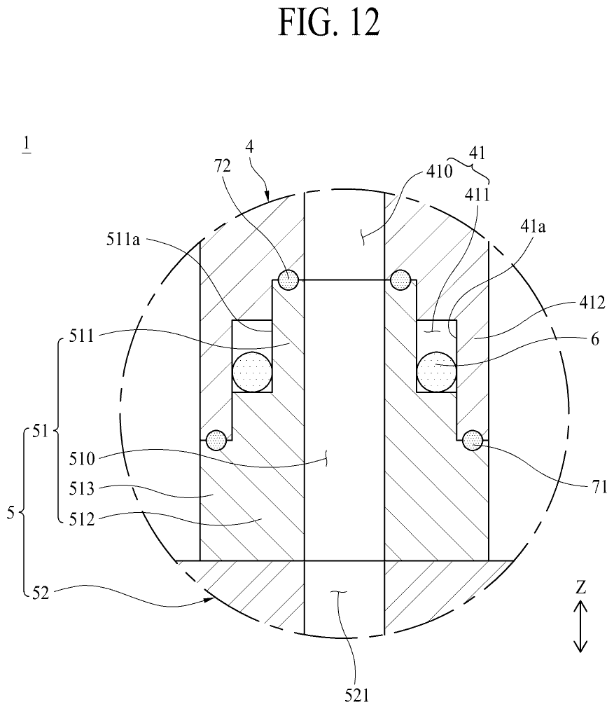

Referring to FIGS. 3 to 12, the substrate processing apparatus 1 according to the present inventive concept may include an outer sealing unit 71 (illustrated in FIG. 12).

The outer sealing unit 71 seals the gap between the gas inflow unit 51 and the gas supply connection unit 41. The outer sealing unit 71 may be disposed at a position outward apart from the sealing unit 6. Therefore, the substrate processing apparatus 1 according to the present inventive concept may be implemented so that the sealing unit 6 and the outer sealing unit 71 maintain sealing between the gas inflow unit 51 and the gas supply connection unit 41 at different positions. Accordingly, the substrate processing apparatus 1 according to the present inventive concept may more reinforce a prevention force which prevents the leakage of the first process gas, and thus, may more decrease the amount of leakage of the first process gas. The outer sealing unit 71 may be formed in a circular ring shape or an oval ring shape. The outer sealing unit 71 may be formed to have a diameter which is greater than the sealing unit 6.

In a case where the outer sealing unit 71 is provided, the gas inflow unit 51 may include a protrusion portion 513 (illustrated in FIG. 12). The protrusion portion 513 protrudes outward from an outer surface of the inflow body 512. The protrusion portion 513 may be disposed under the cover portion 412. In this case, the outer sealing unit 71 may be disposed between the cover portion 412 and the protrusion portion 513 to seal a gap between the cover portion 412 and the protrusion portion 513. Accordingly, the outer sealing unit 71 may seal the gap between the gas supply connection unit 41 and the gas inflow unit 51 at a position outward apart from the sealing unit 6. With respect to the vertical direction (the Z-axis direction), the outer sealing unit 71 may be disposed at a height which is lower than the sealing unit 6. A groove into which the outer sealing unit 71 is inserted may be formed in at least one of the cover portion 412 and the protrusion portion 513.

Referring to FIGS. 3 to 12, the substrate processing apparatus 1 according to the present inventive concept may include an inner sealing unit 72 (illustrated in FIG. 12).

The inner sealing unit 72 seals the gap between the gas inflow unit 51 and the gas supply connection unit 41. The inner sealing unit 72 may be disposed at a position inward apart from the sealing unit 6. Therefore, the substrate processing apparatus 1 according to the present inventive concept may be implemented so that the sealing unit 6 and the inner sealing unit 72 maintain sealing between the gas inflow unit 51 and the gas supply connection unit 41 at different positions. Accordingly, the substrate processing apparatus 1 according to the present inventive concept may more reinforce a prevention force which prevents the leakage of the first process gas, and thus, may more decrease the amount of leakage of the first process gas. The inner sealing unit 72 may be formed in a circular ring shape or an oval ring shape. The inner sealing unit 72 may be formed to have a diameter which is less than the sealing unit 6.

The inner sealing unit 72 may be disposed between the insertion portion 511 and the gas supply connection unit 41 to seal a gap between the insertion portion 511 and the gas supply connection unit 41. Accordingly, the inner sealing unit 72 may seal the gap between the gas supply connection unit 41 and the gas inflow unit 51 at a position inward apart from the sealing unit 6. With respect to the vertical direction (the Z-axis direction), the inner sealing unit 72 may be disposed at a height which is higher than the sealing unit 6. A groove into which the inner sealing unit 72 is inserted may be formed in at least one of the insertion portion 511 and the gas supply connection unit 41.

The substrate processing apparatus 1 according to the present inventive concept may include all of the inner sealing unit 72 and the outer sealing unit 71. In this case, the substrate processing apparatus 1 according to the present inventive concept may more reinforce a sealing force between the gas supply connection unit 41 and the gas inflow unit 51 by using the inner sealing unit 72, the outer sealing unit 71, and the sealing unit 6.

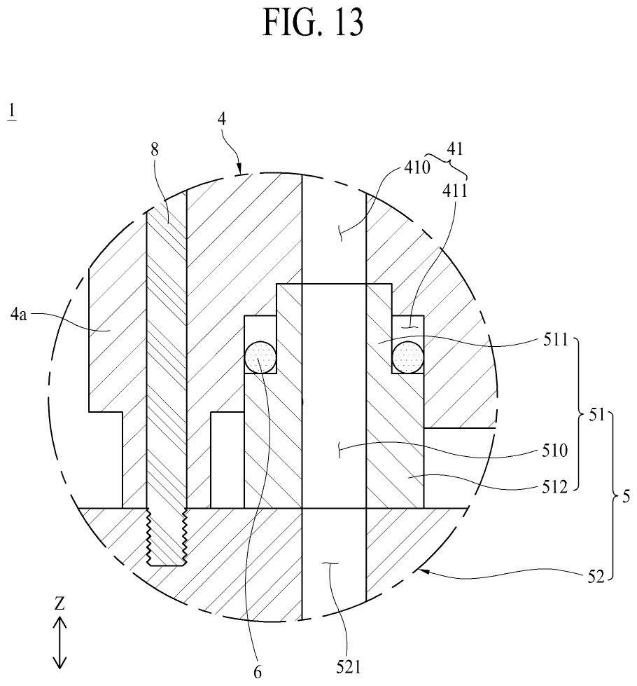

Referring to FIGS. 2 to 13, the substrate processing apparatus 1 according to the present inventive concept may include a coupling unit 8 (illustrated in FIG. 13).

The coupling unit 8 couples the gas supply unit 4 to the gas injection unit 5. The coupling unit 8 may limit a relatively movable distance between the gas supply unit 4 and the gas injection unit 5, and thus, may prevent the leakage of the first process gas through a region between the gas supply unit 4 and the gas injection unit 5. The coupling unit 8 may couple the gas supply unit to the gas injection unit 5.

In a case where the coupling unit 8 is provided, the gas supply unit 4 may include a coupling portion 4a. The coupling portion 4a protrudes outward from an outer surface of the gas supply connection unit 41. Therefore, the coupling unit 8 may couple the gas supply unit 4 to the gas injection unit 5 at a position apart from the sealing unit 6, and thus, may be disposed not to interfere with the sealing unit 6. An upper portion of the coupling unit 8 may be inserted into a coupling groove formed in the coupling portion 4a, and a lower portion of the coupling unit 8 may be inserted into a coupling groove formed in the gas injection unit 5.

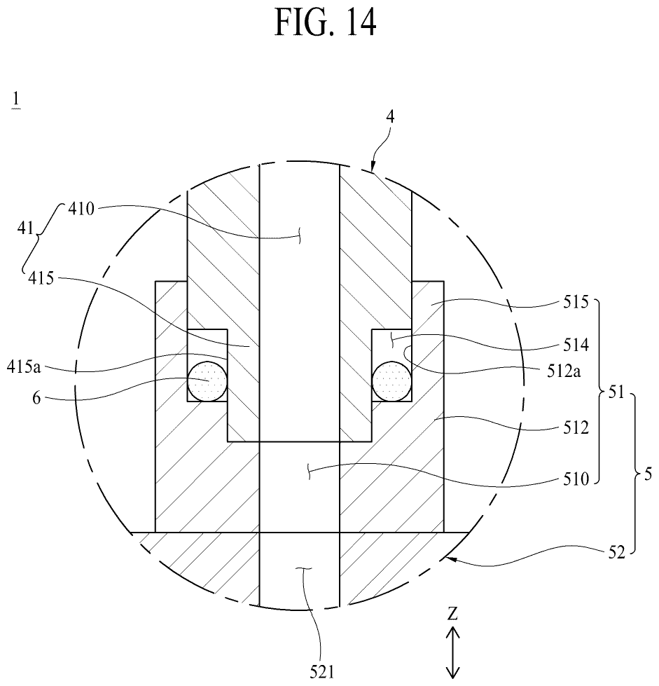

Hereinabove, an embodiment where the gas inflow unit 51 is inserted into the gas supply connection unit 41 has been described, but the substrate processing apparatus 1 according to the present inventive concept may be implemented as an embodiment where the gas supply connection unit 41 is inserted into the gas inflow unit 51. Such an embodiment will be described below in detail with reference to FIGS. 2 to 14.

The gas supply connection unit 41 may include an insertion portion 415. The insertion portion 415 is inserted into the gas inflow unit 51. The insertion portion 415 may be formed to protrude toward the gas inflow unit 51. The first gas supply hole 410 may be formed to pass through the insertion portion 415. The insertion portion 415 may correspond to a lower portion of the gas supply connection unit 41.

In a case where the insertion portion 415 is inserted into the gas inflow unit 51, the sealing unit 6 may be disposed outside the insertion portion 415. Therefore, the sealing unit 6 may be disposed to maintain sealing between the gas inflow unit 51 and the gas supply connection unit 41, in the gas inflow unit 51. Accordingly, even when relative movement caused by deformation occurs between the gas injection unit 5 and the gas supply connection unit 41, the substrate processing apparatus 1 according to the present inventive concept may prevent the leakage of the first process gas through a region between the gas inflow unit 51 and the gas supply connection unit 41. Therefore, the substrate processing apparatus 1 according to the present inventive concept may reduce particles occurring due to the leakage of the first process gas, and thus, may enhance the quality of the substrate S on which the processing process has been performed. Also, the substrate processing apparatus 1 according to the present inventive concept may decrease the amount of gas wasted due to the leakage of the first process gas, and thus, may reduce the process cost.

The sealing unit 6 may be inserted into the gas inflow unit 51. Therefore, the sealing unit 6 may contact each of the gas supply connection unit 41 and the gas inflow unit 51 in the gas inflow unit 51, and thus, may maintain sealing between the gas inflow unit 51 and the gas supply connection unit 41 which move relatively. In this case, the gas inflow unit 51 may include an insertion groove 514. The insertion groove 514 may be implemented as a groove which is formed by a certain depth from an upper surface of the gas inflow unit 51. The insertion groove 514 may be formed to be connected with the gas inflow hole 510.

The insertion portion 415 may be inserted into the insertion groove 514. The insertion portion 415 may be inserted into the insertion groove 514 so as to be movable in the vertical direction (the Z-axis direction). In a case where the insertion portion 415 is provided, the sealing unit 6 may contact each of an inner surface 512a of the gas inflow unit 51 and an outer surface 415a of the insertion portion 415 so as to maintain sealing between the gas inflow unit 51 and the gas supply connection unit 41 which relatively move. The inner surface 512a of the gas inflow unit 51 is an inner surface which is disposed to face the insertion groove 514. The outer surface 415a of the insertion portion 415 is an outer surface which is disposed to face the inner surface 512a of the gas inflow unit 51 with being inserted into the insertion groove 514. The sealing unit 6 may maintain sealing while allowing relative movement of the gas inflow unit 51 and the gas supply connection unit 41 within a range which maintains a state where the sealing unit 6 contacts each of the inner surface 512a of the gas inflow unit 51 and the outer surface 415a of the insertion portion 415. The sealing unit 6 may be coupled to the insertion portion 415 to surround the outer surface 415a of the insertion portion 415.

The gas inflow unit 51 may include a cover portion 515, so as to increase a distance where the sealing unit 6 is maintained with contacting the inner surface 512a of the gas inflow unit 51. The cover portion 515 may protrude upward to cover a portion of an outer surface of the gas supply connection unit 41. An inner surface of the cover portion 515 may be provided in the inner surface 512a of the gas inflow unit 51. Accordingly, a length of the inner surface 512a of the gas inflow unit 51 increases by a length by which the cover portion 515 protrudes upward. Therefore, the substrate processing apparatus 1 according to the present inventive concept may increase a length which enables the sealing unit 6 to maintain sealing while allowing relative movement between the gas inflow unit 51 and the gas supply connection unit 41 by using the cover portion 412.

Although not shown, even when an embodiment is implemented where the gas supply connection unit 41 is inserted into the gas inflow unit 51, the substrate processing apparatus 1 according to the present inventive concept may be implemented to include at least one of the outer sealing unit 71, the inner sealing unit 72, and the coupling unit 8.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A substrate processing apparatus comprising:
a chamber;
a substrate supporting unit for supporting a substrate in the chamber;
a gas injection unit including a plurality of first injection holes injecting a first process gas toward the substrate, and a gas inflow unit for communicating with the first injection holes and allowing the first process gas to flow in;
a gas supply unit for supplying the first process gas to the gas injection unit, the gas supply unit including a gas supply connection unit connected with the gas inflow unit; and
a sealing unit for maintaining sealing between the gas inflow unit and the gas supply connection unit,
wherein the gas inflow unit comprises an insertion portion inserted into the gas supply connection unit, and
the sealing unit is disposed outside the insertion portion to maintain sealing between the gas inflow unit and the gas supply connection unit.

2. The substrate processing apparatus of claim 1, wherein the sealing unit allows relative movement of the gas inflow unit with respect to the gas supply connection unit or allows relative movement of the gas supply connection unit with respect to the gas inflow unit, while maintaining sealing between the gas inflow unit and the gas supply connection unit.

3. The substrate processing apparatus of claim 1, wherein the gas supply connection unit comprises an insertion groove into which the gas inflow unit is inserted,
the gas inflow unit comprises an insertion portion inserted into the insertion groove so as to be movable in a vertical direction, and
the sealing unit contacts each of an outer surface of the insertion portion and an inner surface of the gas supply connection unit facing the insertion groove to maintain sealing between the gas inflow unit and the gas supply connection unit which relatively move.

4. The substrate processing apparatus of claim 3, wherein the gas inflow unit comprises an inflow body inserted into the insertion groove so as to be movable in the vertical direction,
the insertion portion protrudes from an upper surface of the inflow body, and
the sealing unit is coupled to the insertion portion and is disposed over the inflow body.

5. The substrate processing apparatus of claim 4, wherein the gas supply connection unit comprises a cover portion protruding downward to cover a portion of an outer surface of the inflow body.

6. The substrate processing apparatus of claim 3, wherein the outer surface of the insertion portion is provided to include a horizontal cross-sectional surface having an oval shape, and the sealing unit is coupled to the insertion portion to form an oval shape along the outer surface of the insertion portion.

7. The substrate processing apparatus of claim 1, wherein the gas supply connection unit comprises a first gas supply hole formed to include a horizontal cross-sectional surface having an oval shape,
the gas inflow unit comprises a gas inflow hole formed to include a horizontal cross-sectional surface having an oval shape, and
the sealing unit maintains sealing between the gas supply connection unit and the gas inflow unit to prevent leakage of the first process gas flowing from the first gas supply hole to the gas inflow hole.

8. A substrate processing apparatus comprising:
a chamber;
a substrate supporting unit for supporting a substrate in the chamber;
a gas injection unit including a plurality of first injection holes injecting a first process gas toward the substrate, and a gas inflow unit for communicating with the first injection holes and allowing the first process gas to flow in;
a gas supply unit for supplying the first process gas to the gas injection unit, the gas supply unit including a gas supply connection unit connected with the gas inflow unit; and
a sealing unit for maintaining sealing between the gas inflow unit and the gas supply connection unit,
wherein the gas supply connection unit comprises an insertion portion inserted into the gas inflow unit, and
the sealing unit is disposed outside the insertion portion to maintain sealing between the gas inflow unit and the gas supply connection unit.

9. The substrate processing apparatus of claim 8, wherein the gas inflow unit comprises an insertion groove into which the gas supply connection unit is inserted,
the gas supply connection unit comprises an insertion portion inserted into the insertion groove so as to be movable in a vertical direction, and
the sealing unit contacts each of an outer surface of the insertion portion and an inner surface of the gas inflow unit facing the insertion groove to maintain sealing between the gas inflow unit and the gas supply connection unit which relatively move.

10. The substrate processing apparatus of claim 1, wherein the gas supply connection unit comprises a first gas supply hole supplied with the first process gas,
the gas supply unit comprises a second gas supply hole supplied with a second process gas and a gas emission hole through which the second process gas is emitted, and
the gas injection unit comprises a first gas flow path through which the first process gas flows and a second gas flow path which is spatially separated from the first gas flow path, the second process gas flows through the second gas flow path.

11. The substrate processing apparatus of claim 10, wherein the gas injection unit comprises:
a lower plate disposed over the substrate supporting unit;
an upper plate disposed over the lower plate; and
a plurality of flow path protrusions disposed between the lower plate and the upper plate.

12. The substrate processing apparatus of claim 11, wherein the first gas flow path comprises:
a first connection hole formed to pass through the upper plate, the first connection hole connected with a gas inflow hole formed to pass through the gas inflow unit;
a buffer portion disposed at outer portions of the flow path protrusions between the lower plate and the upper plate, the buffer portion connected with the first connection hole; and
the first injection holes formed to pass through the lower plate, the first injection holes connected with the buffer portion.

13. The substrate processing apparatus of claim 11, wherein the second gas flow path comprises:
a plurality of second connection holes formed to pass through the upper plate, the second process gas emitted from the gas emission hole flowing into the plurality of second connection holes;
a plurality of flow path holes formed to respectively pass through the flow path protrusions, the plurality of flow path holes respectively connected with the second connection holes; and
a plurality of second injection holes formed to pass through the lower plate, the plurality of second injection holes respectively connected with the flow path holes.

14. The substrate processing apparatus of claim 10, comprising a lid covering an upper portion of the chamber,
wherein the gas supply unit is inserted into and coupled to the lid, and
a diffusion portion for transferring the second process gas, emitted from the gas emission hole, to the second gas flow path is provided in the lid.

15. The substrate processing apparatus of claim 14, wherein the gas supply unit comprises the gas emission holes provided in plurality,
one side of each of the gas emission holes is connected with the second gas supply hole, and
the other sides of the gas emission holes are connected with the diffusion portion at different portions.

16. The substrate processing apparatus of claim 15, wherein the gas supply connection unit comprises a plurality of first gas supply holes for emitting the first process gas, and
each of the plurality of first gas supply holes is disposed between the gas emission holes in a circumference direction with respect to the second gas supply hole.

17. The substrate processing apparatus of claim 1, further comprising an outer sealing unit sealing a gap between the gas inflow unit and the gas supply connection unit at a position outward apart from the sealing unit.

18. The substrate processing apparatus of claim 1, further comprising an inner sealing unit sealing a gap between the gas inflow unit and the gas supply connection unit at a position inward apart from the sealing unit.

19. The substrate processing apparatus of claim 1, comprising a coupling unit coupling the gas supply unit to the gas injection unit.
